(19) United States
(12) Patent Application Publication
(10) Pub. No.: US 2008/0169855 A1
(43) Pub. Date: Jul. 17, 2008

(54) Apparatus and method for correcting duty cycle of clock signal

(76) Inventors: Won-Hwa Shin, Suwon-si (KR); Sung-Man Park, Seongnam-si (KR); Kwang-Il Park, Yongin-si (KR)

Correspondence Address: LAW OFFICE OF MONICA H CHOI, P O BOX 3424, DUBLIN, OH, 430160204, US

(21) Appl. No.: 11/809,971

(22) Filed: Jun. 4, 2007

(30) Foreign Application Priority Data
Jun. 21, 2006 (KR) 2006-55909

(51) Int. Cl. H03K 3/017

(52) U.S. Cl. 327/175; 327/176

(57) ABSTRACT

An apparatus for correcting a duty cycle of an input clock signal to generate a digitally corrected clock signal includes a duty cycle detector, an analog duty cycle correcting unit, and a digital duty cycle correcting unit. The duty cycle detector generates a duty cycle signal indicating a respective duty cycle of the digitally corrected clock signal. The analog duty cycle correcting unit adjusts a current flowing through a node to adjust the respective duty cycle of the input clock signal for generating an analog corrected clock signal at the node. The digital duty cycle correcting unit adjusts the respective duty cycle of the analog corrected clock signal according to the duty cycle signal for generating the digitally corrected clock signal.

This application claims priority under 35 USC § 119 to Korean Patent Application No. 2006-55909, filed on Jun. 21, 2006 in the Korean Intellectual Property Office, the disclosure of which is incorporated herein in its entirety by reference.

### BACKGROUND OF THE INVENTION

1. Field of the Invention

The present invention relates generally to generation of clock signals, and more particularly, to correcting for a duty cycle of a clock signal using both analog and digital duty cycle corrections.

2. Background of the Invention

Semiconductor memory devices such as DRAM (Dynamic Random Access Memory) and DDR (Double Data Rate) memory, systems for processing video signals and audio signals, and communication systems use a duty cycle correcting circuit for generating a precise clock signal. The duty cycle correcting circuit processes an input clock signal and generates an output clock signal having a desired duty cycle.

A duty cycle represents a value obtained by dividing the time corresponding to the pulse width of a logic high period by the cyclic period of the clock signal in percentage. In general, semiconductor memory devices, signal processing systems, and communication systems require a clock signal having a duty cycle of 50%. To ensure normal operation of the system, a clock signal generated by a duty cycle correcting circuit is desired to have a uniform duty cycle.

FIG. 1 is a circuit diagram of a conventional analog duty cycle correcting circuit. Referring to FIG. 1, the conventional analog duty cycle correcting circuit includes a differential amplifier. The conventional analog duty cycle correcting circuit receives an external clock signal ECLK and an inverted external clock signal ECLKB. The conventional analog duty cycle correcting circuit controls a common mode of the differential amplifier to correct the duty cycle of the external clock signal ECLK and the inverted external clock signal ECLKB for generating corrected clock signals ICLK and ICLKB at output nodes.

However, the conventional analog duty cycle correcting circuit adjusts current through the output nodes for controlling the common mode of the differential amplifier. Such current adjustment increases current consumption. In particular, when the duty cycle of the external clock signal ECLK is excessively distorted, current consumption abruptly increases. Moreover, correcting the duty cycle of the external clock signal ECLK may not be possible.

Furthermore, the conventional analog duty cycle correcting circuit changes both rising edges and falling edges of the external clock signal ECLK when correcting the duty cycle of the external clock signal ECLK. Accordingly, the jitter characteristic of the corrected clock signals ICLK and ICLKB is deteriorated.

### SUMMARY OF THE INVENTION

An apparatus and method for correcting a duty cycle of an input clock signal uses at least one delay unit to generate a digitally corrected clock signal.

Such an apparatus according to an aspect of the present invention includes a duty cycle detector, an analog duty cycle correcting unit, and a digital duty cycle correcting unit. The duty cycle detector generates a duty cycle signal indicating a respective duty cycle of the digitally corrected clock signal. The analog duty cycle correcting unit adjusts a current flowing through a node to adjust the respective duty cycle of the input clock signal for generating an analog corrected clock signal at the node. The digital duty cycle correcting unit adjusts the respective duty cycle of the analog corrected clock signal according to the duty cycle signal for generating the digitally corrected clock signal.

In an embodiment of the present invention, the analog duty cycle correcting unit includes a differential amplifier having the input clock signal and an inverse of the input clock signal applied as inputs at gates of a differential pair of transistors. The node is at a drain of one of the transistors forming the differential amplifier, and the differential amplifier has a controlled common mode voltage.

In another embodiment of the present invention, the duty cycle detector includes a charge pump, a comparator, and a counter. The charge pump is pumped with the digitally corrected clock signal. The comparator compares an output of the charge pump with a reference level representing a desired duty cycle for the digitally corrected clock signal. The counter counts from an initial time point to a final time point when an output of the comparator transitions logically indicating that the output of the charge pump has reached the reference level, to generate the duty cycle signal.

In a further embodiment of the present invention, the digital duty cycle correcting unit includes a delay unit and a clock operating unit. The delay unit delays the analog corrected clock signal with a first delay time according to the duty cycle signal to generate a first delayed analog corrected clock signal. The clock operating unit logically combines the analog corrected clock signal and the first delayed analog corrected clock signal to generate the digitally corrected clock signal.

In an example embodiment of the present invention, the clock operating unit performs an OR or NOR operation on the analog corrected clock signal and the first delayed analog corrected clock signal for increasing the respective duty cycle of the digitally corrected clock signal. Alternatively, the clock operating unit performs an AND or NAND operation on the analog corrected clock signal and the first delayed analog corrected clock signal for decreasing the respective duty cycle of the digitally corrected clock signal.

In another embodiment of the present invention, the delay unit includes a plurality of series-connected delay cells each being controlled by a respective bit value of the duty cycle signal that is a binary value. In that case, the delay cells provide different respective delays.

In a further embodiment of the present invention, an edge control delay unit delays the analog corrected clock signal with a second delay time to generate a second delayed analog corrected clock signal. The second delay time is greater than the first delay time and is independent of the duty cycle signal. In that case, the clock operating unit logically combines the first and second delayed analog corrected clock signals to generate the digitally corrected clock signal.

In another embodiment of the present invention, another digital duty cycle correcting unit adjusts the respective duty cycle of the digitally corrected clock signal to generate a further digitally corrected clock signal according to another duty cycle signal generated by the duty cycle detector for indicating a respective duty cycle of the further digitally corrected clock signal. In that case, the digital duty cycle correcting unit adjusts the respective duty cycle of the analog corrected clock signal also according to the other duty cycle signal for generating the digitally corrected clock signal.

For example in that case, the digital duty cycle correcting unit includes a delay unit and a clock operating unit. The delay unit delays the analog corrected clock signal with a first delay time according to the other duty cycle signal to generate a first delayed analog corrected clock signal. The clock operating unit logically combines the analog corrected clock signal and the first delayed analog corrected clock signal to generate the digitally corrected clock signal.

Also in that case, the other digital duty cycle correcting unit includes another delay unit, an edge control delay unit, and another clock operating unit. The other delay unit delays the digitally corrected clock signal with another first delay time according to the other duty cycle signal to generate a first delayed digitally corrected clock signal. The edge control delay unit delays the digitally corrected clock signal with a second delay time according to the other duty cycle signal to generate a second delayed digitally corrected clock signal, with the second delay time being greater than the other first delay time. The other clock operating unit logically combines the first and second delayed digitally corrected clock signals to generate the further digitally corrected clock signal.

An apparatus for correcting a duty cycle of an input clock signal to generate a digitally corrected clock signal according to another aspect of the present invention includes a delay unit and a clock operating unit. The delay unit delays the input clock signal with a first delay time to generate a first delayed clock signal. The clock operating unit logically combines the input clock signal and the delayed clock signal to generate the digitally corrected clock signal.

In an embodiment of the present invention, such an apparatus further includes a duty cycle detector for generating a duty cycle signal indicating a respective duty cycle of the digitally corrected clock signal. In that case, the delay unit delays the input clock signal with the first delay time depending on the duty cycle signal.

In another embodiment of the present invention, such an apparatus further includes an edge control delay unit for delaying the clock signal with a second delay time to generate a second delayed clock signal. The second delay time is greater than the first delay time, and the second delay time is independent of the duty cycle signal. In that case, the clock operating unit logically combines the first and second delayed clock signals to generate the digitally corrected clock signal.

### BRIEF DESCRIPTION OF THE DRAWINGS

The above and other features and advantages of the present invention will become more apparent when described in detailed exemplary embodiments thereof with reference to the attached drawings in which:

FIG. 1 is a circuit diagram of a conventional analog duty cycle correcting circuit;

FIG. 2 is a block diagram of a duty cycle correcting apparatus, according to an embodiment of the present invention;

FIG. 3A is a block diagram of a digital duty cycle correcting unit of FIG. 2, according to an embodiment of the present invention;

FIG. 3B is a block diagram of the digital duty cycle correcting unit of FIG. 2, according to another embodiment of the present invention;

FIGS. 3C and 3D are example timing diagrams of signals during operation of a digital duty cycle correcting unit of FIG. 7, according to another embodiment of the present invention;

FIG. 3E is an example timing diagram of signals during operation of the digital duty cycle correcting units of FIGS. 3A and 3B, each including an edge control delay unit, according to another embodiment of the present invention;

FIG. 4 is a circuit diagram of delay cells included in delay units of FIG. 3A, 3B, or 7, according to an embodiment of the present invention;

FIG. 5 is a circuit diagram of delay cells included in the delays units of FIG. 3A, 3B, or 7, according to another embodiment of the present invention;

FIG. 6 is a flow chart of steps during operation of the duty cycle correcting apparatus of FIG. 2, according to an embodiment of the present invention; and

FIG. 7 is a block diagram of the digital duty cycle correcting unit of FIG. 2, according to another embodiment of the present invention.

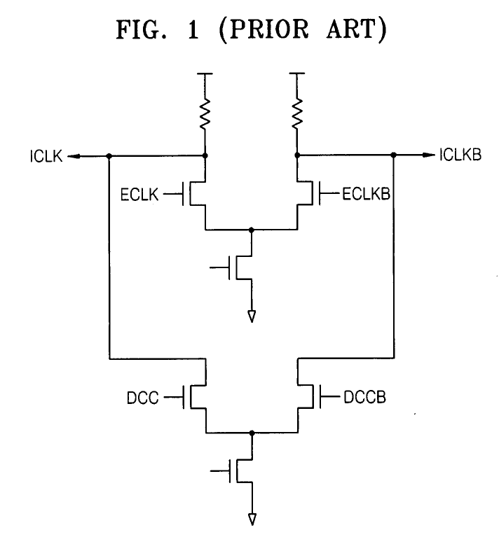

The figures referred to herein are drawn for clarity of illustration and are not necessarily drawn to scale. Elements having the same reference number in FIGS. 1, 2, 3A, 3B, 3C, 3D, 3E, 4, 5, 6, and 7 refer to elements having similar structure and/or function.

### DETAILED DESCRIPTION OF THE INVENTION

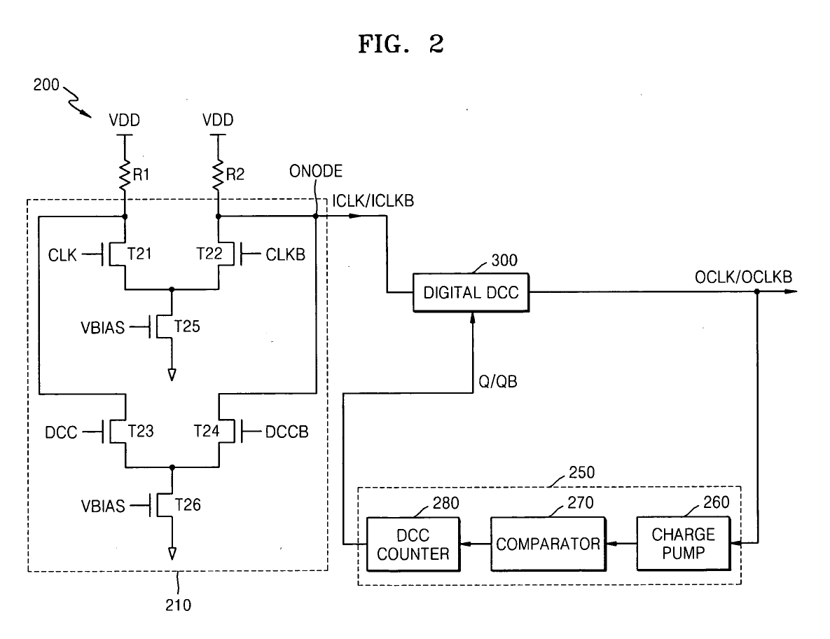

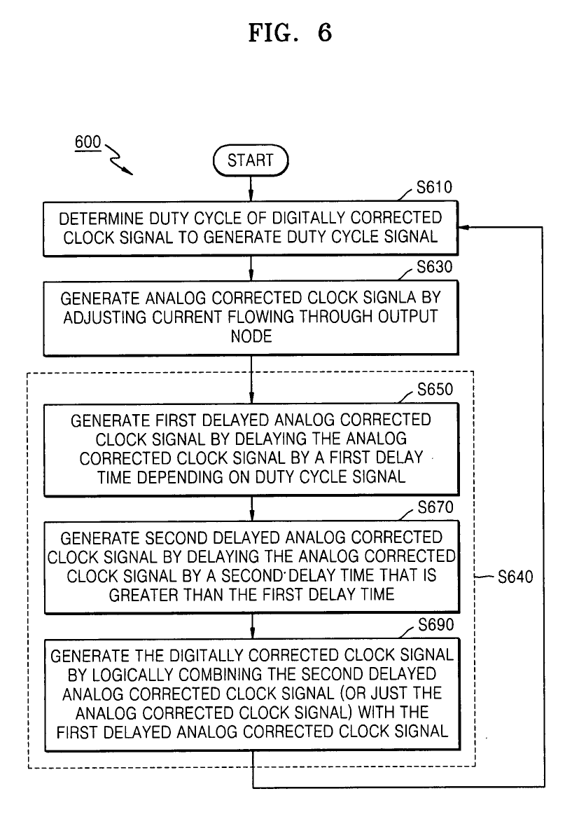

FIG. 2 is a block diagram of a duty cycle correcting apparatus 200 according to an embodiment of the present invention. FIG. 6 shows a flowchart 600 of steps during operation of the duty cycle correcting apparatus 200 of FIG. 2 according to an embodiment of the present invention.

Referring to FIG. 2, the duty cycle correcting apparatus 200 includes a duty cycle detector 250, an analog duty cycle correcting unit 210, and a digital duty cycle correcting unit 300. The duty cycle detector 250 determines a respective duty cycle of a digitally corrected clock signal OCLK/OCLKB output by the duty cycle correcting apparatus 200 (step S610 in FIG. 6). The duty cycle detector 250 generates a duty cycle signal Q/QB indicating such a respective duty cycle of the digitally corrected clock signal OCLK/OCLKB. The duty cycle signal Q/QB is a binary value in one embodiment of the present invention.

The analog duty cycle correcting unit 210 is implemented with a differential amplifier comprised of a differential pair of field effect transistors T21 and T22. The analog duty cycle correcting unit 210 also includes controlling field effect transistors T23 and T24, bias field effect transistors T25 and T26, and bias resistors R1 and R2. One of ordinary skill in the art would know how such components of the analog duty cycle correcting unit 210 are connected from FIG. 2.

The analog duty cycle correcting unit 210 controls a current flowing through an output node ONODE of the analog duty cycle correcting unit 210 to correct the respective duty cycle of an input clock signal CLK/CLKB to generate an analog corrected clock signal ICLK/ICLKB at the output node ONODE (step S630 in FIG. 6). The digital duty cycle correcting unit 300 receives the analog corrected clock signal ICLK/ICLKB from the analog duty cycle correcting unit 210.

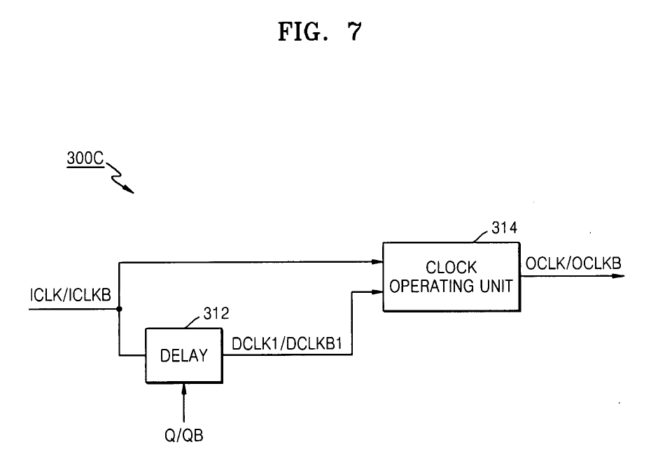

Thereafter, the digital duty cycle correcting unit 300 adjusts the respective duty cycle of the analog corrected clock signal ICLK/ICLKB in response to the duty cycle signal Q/QB to generate the digitally corrected clock signal OCLK/OCLKB (step S640 in FIG. 7). The digital duty cycle correcting unit 300 uses delay of the analog corrected clock signal ICLK/ICLKB for performing duty cycle correction according to an aspect of the present invention.

Note in FIG. 2 that when an analog corrected clock signal ICLK is deemed to be generated at the output node ONODE, then signals Q and OCLK are generated for that analog corrected clock signal ICLK. When an inverse of the analog corrected clock signal ICLKB is deemed to be generated at the output node ONODE, then signals QB and OCLKB are generated for such an inverse of the analog corrected clock signal ICLKB.

FIG. 7 is a block diagram of the digital duty cycle correcting unit 300C (300) of FIG. 2 according to an embodiment of the present invention. Referring to FIG. 7, the digital duty cycle correcting unit 300C includes a delay unit 312 and a clock operating unit 314. The delay unit 312 delays the analog corrected clock signal ICLK/ICLKB by a first delay time D1 to generate a first delayed corrected clock signal DCLK1/DCLKB1 (step S650 of FIG. 6). Such a first delay time D1 depends on the value of the duty cycle signal Q/QB.

The clock operating unit 314 logically combines the first delayed corrected clock signal DCLK1/DCLKB1 and the analog corrected clock signal ICLK/ICLKB to generate the digitally corrected clock signal OCLK/OCLKB (step S690 of FIG. 6). Note that in the embodiment of FIG. 7, a step S670 is not performed in FIG. 6, and step S690 would follow from step S650 in FIG. 6.

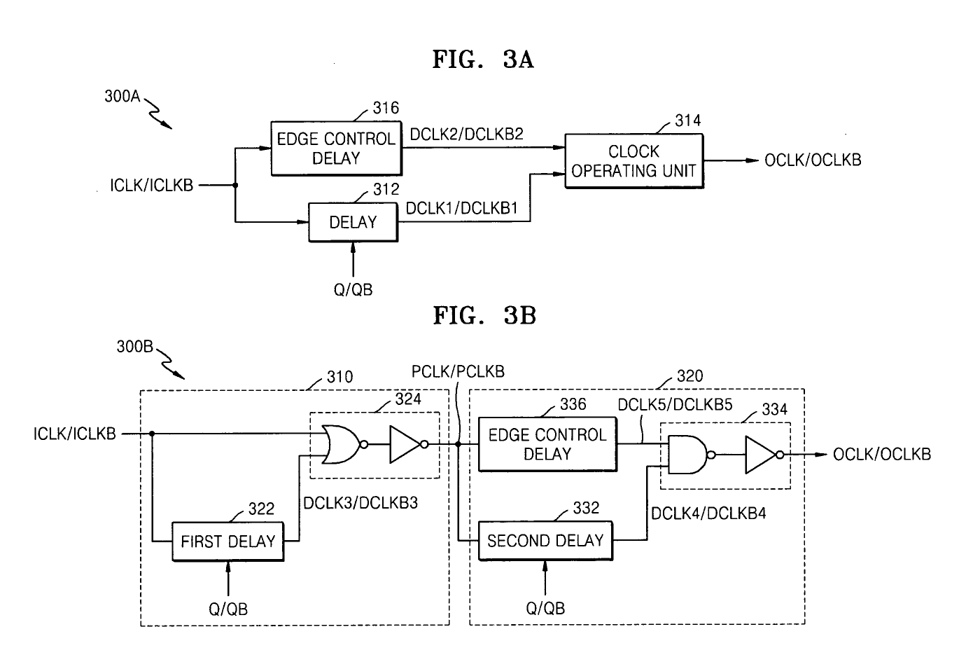

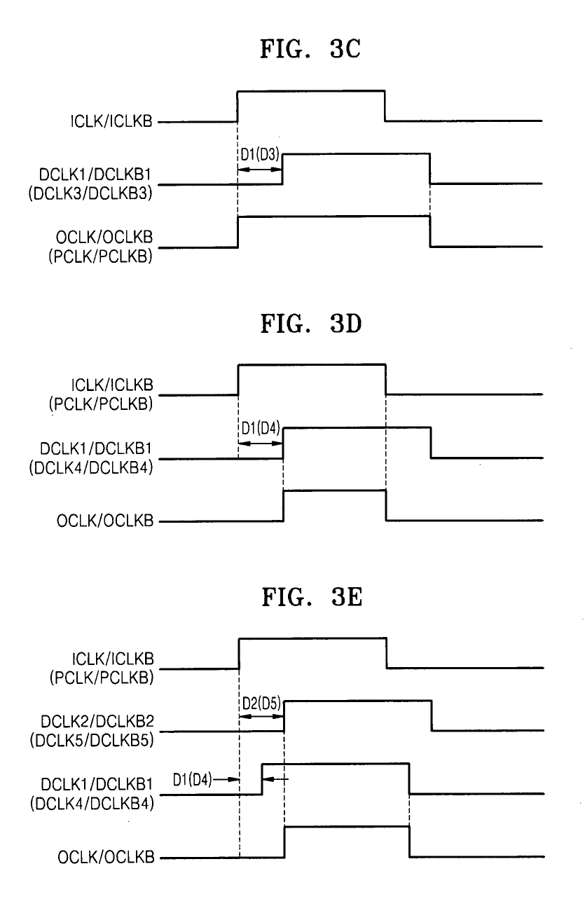

FIGS. 3C and 3D are example timing diagrams of signals during operation of the digital duty cycle correcting unit 300C of FIG. 7. Referring to FIG. 3C, when the respective duty cycle of the analog corrected clock signal ICLK/ICLB is desired to be increased, the clock operating unit 314 performs a logic OR operation or a logic NOR operation on the first delayed corrected clock signal DCLK1/DCLKB1 and the analog corrected clock signal ICLK/ICLKB to generate the digitally corrected clock signal OCLK/OCLKB with increased duty cycle.

Referring to FIG. 3D, when the respective duty cycle of the analog corrected clock signal ICLK/ICLB is desired to be decreased, the clock operating unit 314 performs a logic AND operation or a logic NAND operation on the first delayed corrected clock signal DCLK1/DCLKB1 and the analog corrected clock signal ICLK/ICLKB to generate the digitally corrected clock signal OCLK/OCLKB with decreased duty cycle.

Note that the flow-chart of FIG. 6 returns back to step S610 after step S690 for constantly monitoring and maintaining the duty cycle of the digitally corrected clock signal OCLK/OCLKB to a desired duty cycle. To that end, the duty cycle detector 250 includes a charge pump 260, a comparator 270, and a DCC (duty cycle counting) counter 280.

The charge pump 260 charge-pumps with the digitally corrected clock signal OCLK/OCLKB to generate a charge pumped signal. The level of the charged pumped signal is correlated to the respective duty cycle of the digitally corrected clock signal OCLK/OCLKB. For example, a higher duty cycle of the digitally corrected clock signal OCLK/OCLKB results in a faster increase of the charged pumped signal.

The comparator 270 compares the charged pumped signal with a reference level that is set according to a desired duty cycle of the digitally corrected clock signal OCLK/OCLKB. The comparator 270 makes a logical transition when the charged pumped signal reaches the reference level. Meanwhile, the DCC counter 280 counts from an initial time period such as when the charge pump 260 begins to charge-pump using the digitally corrected clock signal OCLK/OCLKB to a final time point when the charged pumped signal reaches the reference level (i.e., when the output of the comparator makes a logical transition).

Such a count from the DCC counter 280 is a binary value of the duty cycle signal Q/QB. In the example of a higher duty cycle of the digitally corrected clock signal OCLK/OCLKB resulting in a faster increase of the charged pumped signal, a lower binary value of the duty cycle signal Q/QB results. In that case in FIG. 3D, the delay D1 to the first delayed corrected clock signal DCLK1/DCLKB1 is higher to decrease the duty cycle of the digitally corrected clock signal OCLK/OCLKB to the desired duty cycle.

FIG. 3A is a block diagram of the digital duty cycle correcting unit 300A (300) of FIG. 2 according to another embodiment of the present invention. Elements having the same reference number in FIGS. 7 and 3A refer to elements having similar structure and/or function.

However comparing FIGS. 7 and 3A, the digital duty cycle correcting unit 300A of FIG. 3A further includes an edge control delay unit 316. FIG. 3E is a timing diagram of signals during operation of the digital duty cycle correcting unit 300A of FIG. 3A according to an embodiment of the present invention.

Referring to FIGS. 3A and 3E, the edge control delay 316 delays the analog corrected clock signal ICLK/ICLKB by a second delay time D2 to generate a second delayed corrected clock signal DCLK2/DCLKB2 (step S670 of FIG. 6). The second delay time D2 is greater than the first delay time D1, and the second delay time D2 does not depend on the duty cycle signal Q/QB, in one embodiment of the present invention.

Further referring to FIGS. 3A and 3E, the clock operating unit 314 logically combines the first and second delayed corrected clock signals DCLK1/DCLKB1 and DCLK2/DCLK2B to generate the digitally corrected clock signal OCLK/OCLKB. Note that in the embodiment of FIG. 3A, the step S670 is performed in FIG. 6.

In FIGS. 3A and 3E, the second delay time D2 is different from the first delay time D1 with the second delay time D2 being greater than the first delay time D1. Use of the edge control delay 316 may prevent the rising edge of the digitally corrected clock signal OCLK/OCLKB from dynamically varying.

In detail, since the second delay time D2 is longer than the first delay time D1, if a logic AND operation is performed between the first and second delayed corrected clock signals DCLK1/DCLKB1 and DCLK2/DCLKB2, the digitally corrected clock signal OCLK/OCLKB is delayed from the input clock signal ICLK/ICLKB by the second delay time D2. Here, the second delay time D2 is not varied dynamically with the duty cycle signal Q/QB. Instead, the second delay time D2 is set as a predetermined value. Therefore, by using the edge control delay 316, the digitally corrected clock signal OCLK/OCLKB may be controlled to not vary dynamically with the duty cycle signal Q/QB.

In contrast, referring to FIGS. 7 and 3D, when the digital duty cycle correcting unit 300C does not include the edge control delay 316, the digitally corrected clock signal OCLK/OCLKB is delayed from the input clock signal ICLK/ICLKB by the first delay time D1 which varies dynamically with the duty cycle value Q/QB. Thus, the rising edge of the digitally corrected clock signal OCLK/OCLKB dynamically varies with the duty cycle value Q/QB in FIGS. 7 and 3D.

FIG. 3B is a block diagram of the digital duty cycle correcting unit 300B (300) of FIG. 2 according to another embodiment of the present invention. Referring to FIG. 3B, the digital duty cycle correcting unit 300B includes a first duty cycle corrector 310 and a second duty cycle corrector 320.

The first duty cycle corrector 310 includes a first delay unit 322 and a first clock operating unit 324. The second duty cycle corrector 320 includes a second delay unit 332, an edge control delay unit 336, and a second clock operating unit 334.

The first duty cycle corrector 310 is similar to the digital duty cycle correcting unit 300C of FIG. 7. The second duty cycle corrector 320 is similar to the digital duty cycle correcting unit 300A of FIG. 3A.

Referring to FIGS. 3B, 3C, and 3E, the first delay unit 322 delays an analog corrected clock signal ICLK/ICLKB by a third delay time D3 to generate a third delayed analog corrected clock signal DCLK3/DCLKB3. The first clock operating unit 324 performs a logic operation on the third delayed corrected clock signal DCLK3/DCLKB3 and the analog corrected clock signal ICLK/ICLKB to generate a digitally corrected clock signal PCLK/PCLKB.

The second delay unit 332 delays the digitally corrected clock signal PCLK/PCLKB by a fourth delay time D4 to generate a fourth delayed corrected clock signal DCLK4/DCLKB4. The edge control delay unit 336 delays the digitally corrected clock signal PCLK/PCLKB by a fifth delay time D5 to generate a fifth delayed corrected clock signal DCLK5/DCLKB5. The third and fourth delay times D3 and D4 each depend on the value of the duty cycle signal Q/QB. The fifth delay time D5 is set to be greater than the fourth delay time D4 and is independent of the duty cycle signal Q/QB.

The second clock operating unit 334 performs a logic operation on the fourth and fifth delayed corrected clock signals DCLK4/DCLKB4 and DCLK5/DCLKB5 to generate the further digitally corrected clock signal OCLK/OCLKB. The duty cycle detector 250 in FIG. 2 generates the duty cycle signal Q/QB from the further digitally corrected clock signal OCLK/OCLKB in FIG. 3B to indicate the respective duty cycle of the further digitally corrected clock signal OCLK/OCLKB.

In the example of FIG. 3B, the duty cycle of the analog corrected clock signal ICLK/ICLKB is increased since the first clock operating unit 324 performs an OR operation. On the other hand, the duty cycle of the digitally corrected clock signal PCLK/PCLKB is decreased since the second clock operating unit 334 performs an AND operation.

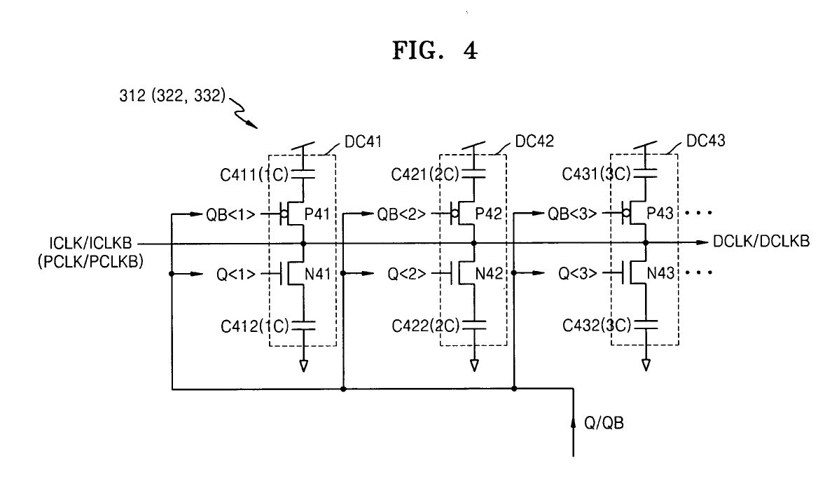

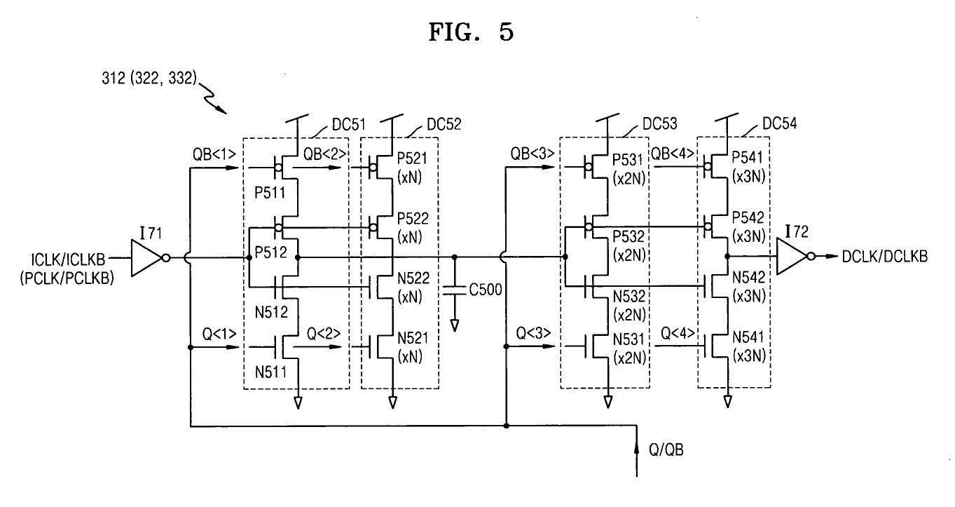

FIG. 4 shows a circuit diagram for an example delay unit that may be any of the delay units 312, 322 and 332 in FIGS. 3A, 3B, and 7, according to an embodiment of the present invention. FIG. 5 shows a circuit diagram for an example delay unit that may be any of the delay units 312, 322 and 332 in FIGS. 3A, 3B, and 7, according to another embodiment of the present invention.

Referring to FIG. 4, the delay unit includes a plurality of delay cells DC41, DC42, and DC43 that are connected in series. Each of the delay cells DC41, DC42, and DC43 has a respective PMOSFET (P41, P42, or P43), a respective NMOSFET (N41, N42, or N43), a respective high voltage supply capacitor (C411, C421, or C431), and a respective low voltage supply capacitor (C412, C422, or C432) connected in series as illustrated in FIG. 4.

Each of the series-connected delay cells DC41, DC42, and DC43 provides a respective delay according to a respective bit value of the duty cycle signal Q/QB. For example in FIG. 4, the first delay cell DC41 is controlled by a most significant bit value Q<1> and QB<1> of the duty cycle signal, as applied on the gates of MOSFETs N41 and P41, respectively. The second delay cell DC42 is controlled by a second most significant bit value Q<2> and QB<2> of the duty cycle signal, as applied on the gates of MOSFETs N42 and P42, respectively. The third delay cell DC43 is controlled by a third most significant bit value Q<3> and QB<3> of the duty cycle signal, as applied on the gates of MOSFETs N43 and P43, respectively.

The capacitance value of the capacitors in each of the delay cells DC41, DC42, and DC43 is different such that the delay cells DC41, DC42, and DC43 provide different delays in response to the respective bit values of the duty cycle signal. For example, the capacitors C411 and C412 in the first delay cell DC41 each have a capacitance value of 1C. The capacitors C421 and C422 in the second delay cell DC42 each have a capacitance value of 2C. The capacitors C431 and C432 in the third delay cell DC43 each have a capacitance value of 3C.

Referring to FIG. 5, the delay unit includes delay cells DC51 DC52 coupled in series and delay cells DC53 and DC 54 coupled in series, and with coupling between the delay cells DC51 and DC53 as illustrated in FIG. 5. Each of the delay cells DC51, DC52, DC53, and DC54 has respective PMOSFETs (P511 and P512, P521 and P522, P531 and P532, or P541 and P542) and respective NMOSFETs (N511 and N512, N521 and N522, N531 and N532, or N541 and N542) connected in series as illustrated in FIG. 5. In addition, the delay unit of FIG. 5 includes inverters 171 and 172 and a capacitor C500 connected as illustrated in FIG. 5.

Each of the delay cells DC51, DC52, DC53, and DC54 provides a respective delay according to a respective bit value of the duty cycle signal Q/QB. For example in FIG. 5, the first delay cell DC51 is controlled by a most significant bit value Q<1> and QB<1> of the duty cycle signal, as applied on the gates of MOSFETs N511 and P511, respectively. The second delay cell DC52 is controlled by a second most significant bit value Q<2> and QB<2> of the duty cycle signal, as applied on the gates of MOSFETs N521 and P521, respectively. The third delay cell DC53 is controlled by a third most significant bit value Q<3> and QB<3> of the duty cycle signal, as applied on the gates of MOSFETs N531 and P531, respectively. The fourth delay cell DC54 is controlled by a fourth most significant bit value Q<4> and QB<4> of the duty cycle signal, as applied on the gates of MOSFETs N541 and P541, respectively.

The delay cells DC51, DC52, DC53 and DC54 have different driving capacity for providing different respective delays in response to the respective bit values of the duty cycle signal. For example, the MOSFETs P521, P522, N522, and N521 of the second delay cell DC52 have driving capacity of N (a natural number) times that of the MOSFETs P511, P512, N512, and N511 of the first delay cell DC51.

Furthermore, the MOSFETs P531, P532, N532, and N531 of the third delay cell DC53 have driving capacity of 2N times that of the MOSFETs P511, P512, N512, and N511 of the first delay cell DC51. Additionally, the MOSFETs P541, P542, N542, and N541 of the fourth delay cell DC54 have driving capacity of 3N times that of the MOSFETs P511, P512, N512, and N511 of the first delay cell DC51.

By using such a delay unit of FIG. 4 or 5 and the edge control unit 316 or 336 for correcting the duty cycle of an input clock signal ICLK/ICLKB, a rising edge or a falling edge of the corrected clock signal is locked to improve jitter characteristics. In addition, current consumption may be conserved by performing both analog duty cycle correction and digital duty cycle correction.

While the present invention has been particularly shown and described with reference to example embodiments thereof, it will be understood by those of ordinary skill in the art that various changes in form and details may be made therein without departing from the spirit and scope of the present invention as defined by the following claims.

The present invention is limited only as defined in the following claims and equivalents thereof.

What is claimed is:

1. An apparatus for correcting a duty cycle of an input clock signal to generate a digitally corrected clock signal, comprising:
a duty cycle detector for generating a duty cycle signal indicating a respective duty cycle of the digitally corrected clock signal;
an analog duty cycle correcting unit for adjusting a current flowing through a node to adjust the respective duty cycle of the input clock signal for generating an analog corrected clock signal at the node; and
a digital duty cycle correcting unit that adjusts the respective duty cycle of the analog corrected clock signal according to the duty cycle signal for generating the digitally corrected clock signal.

2. The apparatus of claim 1, wherein the analog duty cycle correcting unit includes:
a differential amplifier having the input clock signal and an inverse of the input clock signal applied as inputs at gates of a differential pair of transistors, wherein the node is at a drain of one of the transistors forming the differential amplifier, and wherein the differential amplifier has a controlled common mode voltage.

3. The apparatus of claim 1, wherein the duty cycle detector includes:
a charge pump that is pumped with the digitally corrected clock signal;
a comparator for comparing an output of the charge pump with a reference level representing a desired duty cycle for the digitally corrected clock signal; and
a counter that counts from an initial time point to a final time point when an output of the comparator transitions logically indicating that the output of the charge pump has reached the reference level, to generate the duty cycle signal.

4. The apparatus of claim 1, wherein the digital duty cycle correcting unit includes:
a delay unit for delaying the analog corrected clock signal with a first delay time according to the duty cycle signal to generate a first delayed analog corrected clock signal; and
a clock operating unit for logically combining the analog corrected clock signal and the first delayed analog corrected clock signal to generate the digitally corrected clock signal.

5. The apparatus of claim 4, wherein the clock operating unit performs an OR or NOR operation on the analog corrected clock signal and the first delayed analog corrected clock signal for increasing the respective duty cycle of the digitally corrected clock signal, and wherein the clock operating unit performs an AND or NAND operation on the analog corrected clock signal and the first delayed analog corrected clock signal for decreasing the respective duty cycle of the digitally corrected clock signal.

6. The apparatus of claim 4, wherein the delay unit includes:
a plurality of series-connected delay cells each being controlled by a respective bit value of the duty cycle signal that is a binary value,
wherein the delay cells provide different respective delays.

7. The apparatus of claim 1, further comprising:
a delay unit for delaying the analog corrected clock signal with a first delay time according to the duty cycle signal to generate a first delayed analog corrected clock signal;
an edge control delay unit for delaying the analog corrected clock signal with a second delay time to generate a second delayed analog corrected clock signal, wherein the second delay time is greater than the first delay time, and wherein the second delay time is independent of the duty cycle signal; and
a clock operating unit for logically combining the first and second delayed analog corrected clock signals to generate the digitally corrected clock signal.

8. The apparatus of claim 1, further comprising:
another digital duty cycle correcting unit that adjusts the respective duty cycle of the digitally corrected clock signal to generate a further digitally corrected clock signal according to another duty cycle signal generated by the duty cycle detector for indicating a respective duty cycle of the further digitally corrected clock signal,
wherein the digital duty cycle correcting unit adjusts the respective duty cycle of the analog corrected clock signal also according to the other duty cycle signal for generating the digitally corrected clock signal.

9. The apparatus of claim 8, wherein the digital duty cycle correcting unit includes:
a delay unit for delaying the analog corrected clock signal with a first delay time according to the other duty cycle signal to generate the first delayed analog corrected clock signal; and
a clock operating unit for logically combining the analog corrected clock signal and the first delayed analog corrected clock signal to generate the digitally corrected clock signal,
and wherein the other digital duty cycle correcting unit includes:
another delay unit for delaying the digitally corrected clock signal with another first delay time according to the other duty cycle signal to generate a first delayed digitally corrected clock signal;
an edge control delay unit for delaying the digitally corrected clock signal with a second delay time to generate a second delayed digitally corrected clock signal, wherein the second delay time is greater than the other first delay time, and wherein the second delay time is independent of the duty cycle signal; and
another clock operating unit for logically combining the first and second delayed digitally corrected clock signals to generate the further digitally corrected clock signal.

10. An apparatus for correcting a duty cycle of an input clock signal to generate a digitally corrected clock signal, comprising:
a delay unit for delaying the input clock signal with a first delay time to generate a first delayed clock signal; and
a clock operating unit for logically combining the input clock signal and the delayed clock signal to generate the digitally corrected clock signal.

11. The apparatus of claim 10, further comprising:
a duty cycle detector for generating a duty cycle signal indicating a respective duty cycle of the digitally corrected clock signal,
wherein the delay unit delays the input clock signal with the first delay time depending on the duty cycle signal.

12. The apparatus of claim 10, further comprising:
an edge control delay unit for delaying the analog corrected clock signal with a second delay time to generate a second delayed analog corrected clock signal, wherein the second delay time is greater than the first delay time, and wherein the second delay time is independent of the duty cycle signal;
and wherein the clock operating unit logically combines the first and second delayed clock signals to generate the digitally corrected clock signal.

13. The apparatus of claim 10, wherein the clock operating unit performs an OR or NOR operation on the input clock signal and the first delayed clock signal for increasing the respective duty cycle of the digitally corrected clock signal, and wherein the clock operating unit performs an AND or NAND operation on the input clock signal and the first delayed clock signal for decreasing the respective duty cycle of the digitally corrected clock signal.

14. The apparatus of claim 10, wherein the delay unit includes:
a plurality of series-connected delay cells each being controlled by a respective bit value of the duty cycle signal that is a binary value,
wherein the delay cells provide different respective delays.

15. A method of correcting a duty cycle of an input clock signal to generate a digitally corrected clock signal, comprising:
generating a duty cycle signal indicating a respective duty cycle of the digitally corrected clock signal;
adjusting a current flowing through a node to adjust the respective duty cycle of the input clock signal for generating an analog corrected clock signal at the node; and
adjusting the respective duty cycle of the analog corrected clock signal according to the duty cycle signal for generating the digitally corrected clock signal.

16. The method of claim 15, wherein the step of generating the duty cycle signal includes the steps of:
charge pumping with the digitally corrected clock signal to generate a charge pumped signal;
comparing the charge pumped signal with a reference level that indicates a desired duty cycle for the digitally corrected clock signal; and
counting from an initial time point to a final time point when the charged pumped signal has reached the reference level to generate the duty cycle signal.

17. The method of claim 15, wherein the step of adjusting the respective duty cycle of the analog corrected clock signal includes the steps of:
delaying the analog corrected clock signal with a first delay time according to the duty cycle signal to generate a first delayed analog corrected clock signal; and
logically combining the analog corrected clock signal and the first delayed analog corrected clock signal to generate the digitally corrected clock signal.

18. The method of claim 17, wherein the step of adjusting the respective duty cycle of the analog corrected clock signal further includes the steps of:
delaying the analog corrected clock signal with a second delay time to generate a second delayed analog corrected clock signal, wherein the second delay time is greater than the first delay time, and wherein the second delay time is independent of the duty cycle signal; and
logically combining the first and second delayed analog corrected clock signals to generate the digitally corrected clock signal.

19. The method of claim 17, wherein the step of logically combining includes the steps of:
performing an OR or NOR operation on the analog corrected clock signal and the first delayed analog corrected clock signal for increasing the respective duty cycle of the digitally corrected clock signal; and
performing an AND or NAND operation on the analog corrected clock signal and the first delayed analog corrected clock signal for decreasing the respective duty cycle of the digitally corrected clock signal.

20. The method of claim 15, further comprising:
adjusting the respective duty cycle of the digitally corrected clock signal to generate a further digitally corrected clock signal according to another duty cycle signal that indicates a respective duty cycle of the further digitally corrected clock signal,
wherein the digitally corrected clock signal is generated from adjusting the respective duty cycle of the analog corrected clock signal also according to the other duty cycle signal.
